(19) United States
(12) Patent Application Publication
(10) Pub. No.: US 2012/0105092 A1
(43) Pub. Date: May 3, 2012

(54) DEFECT INSPECTING APPARATUS AND DEFECT INSPECTING METHOD

(75) Inventors: Manabu Abiru, Osaka-shi (JP); Kazutoshi Kida, Osaka-shi (JP)

(73) Assignee: SHARP KABUSHIKI KAISHA, Osaka-shi (JP)

(21) Appl. No.: 13/382,271

(22) PCT Filed: Apr. 9, 2010
(86) PCT No.: PCT/JP2010/002624

§ 371 Date: Jan. 4, 2012

(30) Foreign Application Priority Data
Sep. 29, 2009 (JP) 2009-224092

(51) Int. Cl. G01R 31/26

(52) U.S. Cl. 324/760.01

(57) ABSTRACT

An evaluation apparatus includes a lighting control section for lighting a liquid crystal display panel including switch-type touch sensors, a pressing section for pressing the liquid crystal display panel that is being lit, and a sensor data acquisition section for acquiring outputs from touch sensors disposed within a region of the liquid crystal display panel that is pressed by the pressing section. The pressing section is made of a material having transparency. With this apparatus, it is possible to inspect switch-type touch sensors of a liquid crystal display panel for defects by checking a display state in a region to which a load is being applied.

### REFERENCE TO RELATED APPLICATIONS

This application is the national stage under 35 USC 371 of International Application No. PCT/JP2010/002624, filed Apr. 9, 2010, which claims the priority of Japanese Patent Application No. 2009-224092, filed Sep. 29, 2009, the entire contents of which are incorporated herein by reference.

### TECHNICAL FIELD

The present invention relates to apparatus and method for inspecting, for defects, a liquid crystal display panel including a switch-type touch sensor.

### BACKGROUND ART

Liquid crystal display panels are subjected to various inspections in order to check whether or not there is a defect caused in a production stage. One of generally employed methods is a method for checking whether or not there is a defect by pressing a liquid crystal display panel.

Patent Literature 1 discloses an evaluation apparatus for performing an evaluation test of a liquid crystal panel.

FIG. 12 is a schematic view illustrating a configuration of the evaluation apparatus disclosed in Patent Literature 1.

As shown in FIG. 12, the liquid crystal panel evaluation apparatus disclosed in Patent Literature 1 includes a jig 110 for pressing a surface of a liquid crystal display panel 102, a test machine main body 101 for applying a load on the liquid crystal display panel 102 via the jig 110, and a control device 103 for controlling the test machine main body 101 so that the load applied to the liquid crystal display panel 102 via the jig 110 becomes a predetermined load pattern.

Further, the liquid crystal display panel evaluation apparatus disclosed in Patent Literature 1 includes an imaging device 104 for imaging how a display color of the liquid crystal display panel 102 changes immediately after the load applied to the liquid crystal display panel 102 is removed. According to the liquid crystal display panel evaluation apparatus disclosed in Patent Literature 1, it is possible to judge whether a part of the liquid crystal display panel 102 to which the load was applied is normal or defective, by carrying out image processing with respect to an image taken by the imaging device 104.

Moreover, in recent years, in-cell touch panels (hereinafter abbreviated as in-cell TP) having a touch panel function within a liquid crystal panel have been developed. Mainly known as the in-cell TPs are light-detection type in-cell TPs which detect light and switch-type in-cell TPs which detect a pressed pressure. Of the two types of in-cell TPs, the switch-type in-cell TPs require, at a panel display inspection step in a production stage, not only checking of operation of touch sensors in a liquid crystal display panel, but also checking of influence on display caused when the liquid crystal display panel is pressed.

### CITATION LIST

### Patent Literature 1

Japanese Patent Application Publication, Tokukai, No. 2000-28482 A (Publication Date: Jan. 28, 2000)

### SUMMARY OF INVENTION

The liquid crystal panel evaluation apparatus disclosed in Patent Literature 1 is for evaluating a phenomenon in which a trace of a load applied to the liquid crystal display panel 102 via the jig 110 remains as unevenness. Accordingly, a metal bar which is not transparent is used as the jig 110 that is used to apply a load on the liquid crystal display panel 102. According to the liquid crystal panel evaluation apparatus disclosed in Patent Literature 1, it is therefore impossible to check, in a state in which the load is being applied with the use of the jig 110, a display state of a region of the liquid crystal display panel 102 to which region the load is being applied.

The present invention was attained in view of the above problems, and an object of the present invention is to inspect, for defects, touch sensors of a liquid crystal display panel including switch-type touch sensors by checking a display state of a region to which a load is being applied.

In order to attain the above object, a defect inspecting apparatus of the present invention for inspecting touch sensors of a liquid crystal display panel for defects, the touch sensors being switch-type touch sensors, includes: panel lightning means for lighting the liquid crystal display panel to be inspected; a pressing section for pressing the liquid crystal display panel that is being lit; and an output acquisition section for acquiring outputs from touch sensors disposed within a region of the liquid crystal display panel which region is pressed by the pressing section, the pressing section being made of a material having transparency.

In order to attain the above object, a defect inspecting method of the present invention for inspecting touch sensors of a liquid crystal display panel for defects, the touch sensors being switch-type touch sensors, includes the steps of: lighting the liquid crystal display panel to be inspected; causing a pressing section made of a material having transparency to press the liquid crystal display panel that is being lit; and acquiring outputs from touch sensors disposed within a region of the liquid crystal display panel which region is pressed by the pressing section.

The liquid crystal display panel including the switch-type touch sensors has not only a function of displaying an image when it is lit, but also a function of detecting pressing when it is pressed, i.e., function as a touch panel.

According to the arrangement, the panel lightning means lights the liquid crystal display panel including the switch-type touch sensors, i.e., causes the liquid crystal display panel to display an image. The pressing section presses the liquid crystal display panel lit by the lighting means. Then, the output acquisition section acquires outputs from touch sensors within a region of the liquid crystal display panel which region is being pressed. It is therefore possible to check operation of the touch sensors within the pressed region.

The pressing section is made of a material having transparency. Accordingly, in a state in which the liquid crystal display panel is being lit and being pressed, it is possible to check a lighting state within the region of the liquid crystal display panel which region is being pressed. This makes it possible to check presence or absence of a lighting defect which occurs when the liquid crystal display panel is lit and pressed. According to the arrangement, it is thus possible to inspect, for defects, switch-type touch sensors of a liquid crystal display panel by checking a display state of a region to which a load is being applied.

A defect inspecting apparatus of the present invention for inspecting touch sensors of a liquid crystal display panel for defects, the touch sensors being switch-type touch sensors, includes: panel lightning means for lighting the liquid crystal display panel to be inspected; a pressing section for pressing the liquid crystal display panel that is being lit; and an output acquisition section for acquiring outputs from touch sensors disposed within a region of the liquid crystal display panel which region is pressed by the pressing section, the pressing section being made of a material having transparency.

A defect inspecting method of the present invention for inspecting touch sensors of a liquid crystal display panel for defects, the touch sensors being switch-type touch sensors, includes the steps of: lighting the liquid crystal display panel to be inspected; causing a pressing section made of a material having transparency to press the liquid crystal display panel that is being lit; and acquiring outputs from touch sensors disposed within a region of the liquid crystal display panel which region is pressed by the pressing section.

According to the arrangement, it is possible to inspect switch-type touch sensors of a liquid crystal display panel for defects by checking a display state of a region to which a load is being applied.

### BRIEF DESCRIPTION OF DRAWINGS

FIG. 1

FIG. 1 is a schematic view illustrating a configuration of an evaluation apparatus of Embodiment 1 of the present invention.

FIG. 2

FIG. 2 is a perspective view illustrating a pressing section of the evaluation apparatus of FIG. 1 and members stacked within a placing region.

FIG. 3

FIG. 3 is a cross-sectional view illustrating a configuration of part of a pixel of a liquid crystal display panel including a switch-type touch sensor.

FIG. 4

FIG. 4 is a plan view illustrating a configuration of a touch electrode of a touch sensor.

FIG. 5

FIG. 5 is a cross-sectional view illustrating a contact part of the touch sensor.

FIG. 6

FIG. 6 is a diagram illustrating an equivalent circuit of a pixel of a liquid crystal display panel in a case where a rib and a switch TFT become conductive with each other.

FIG. 7

FIG. 7 is a diagram illustrating a configuration of a liquid crystal display device in which a defect is occurring due to misalignment between a rib and a touch electrode.

FIG. 8

FIG. 8 is a diagram illustrating a first modification of the evaluation apparatus of FIG. 1.

FIG. 9

FIG. 9 is a diagram illustrating a second modification of the evaluation apparatus of FIG. 1.

FIG. 10

FIG. 10 is a schematic view illustrating a configuration of an evaluation apparatus of Embodiment 2.

FIG. 11

FIG. 11 is a schematic view illustrating a configuration of an evaluation apparatus of Embodiment 3.

FIG. 12

FIG. 12 is a schematic view illustrating a configuration of a conventional evaluation apparatus.

### DETAILED DESCRIPTION OF THE INVENTION

Embodiments of the present invention are described below in detail.

### Embodiment 1

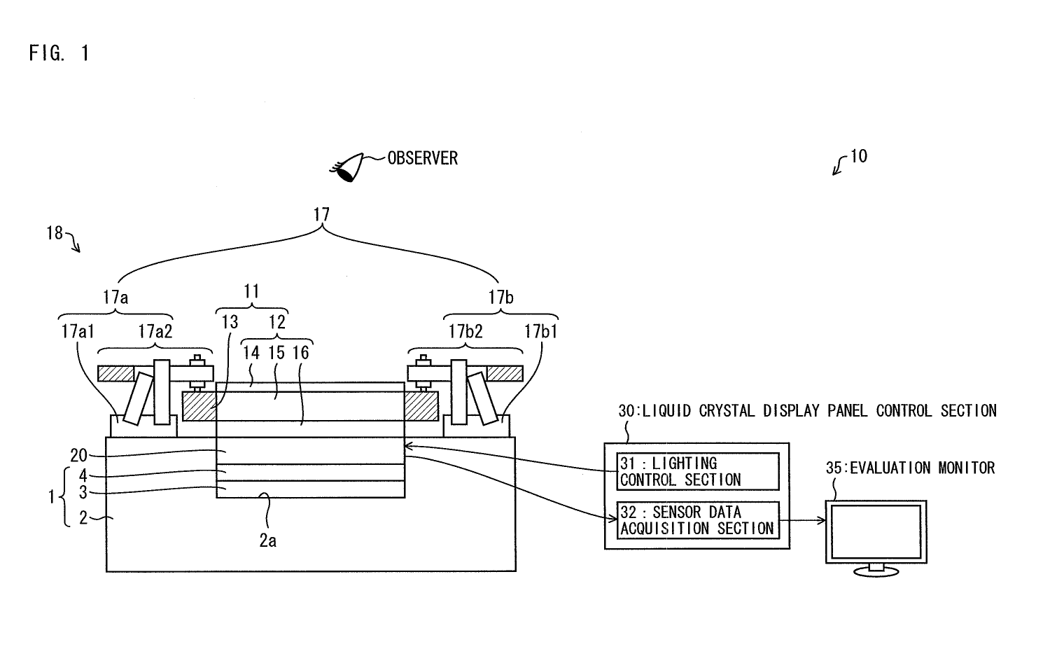

Embodiment 1 of an evaluation apparatus of the present invention is described below with reference to FIGS. 1 through 9.

FIG. 1 is a schematic view illustrating a configuration of an evaluation apparatus 10 of the present embodiment.

The evaluation apparatus (defect inspecting apparatus) 10 is for inspecting a lighting state of a liquid crystal display panel 20 in a state in which the liquid crystal display panel 20 is being pressed. The liquid crystal display panel 20 is a liquid crystal display panel having an in-cell type touch panel function in which switch-type touch sensors are provided in the panel. In the liquid crystal display panel 20, pixels and switch-type touch sensors are disposed in a dot-matrix manner. Details of the liquid crystal display panel 20 are described later.

As shown in FIG. 1, the evaluation apparatus 10 includes a main body 18, a liquid crystal display panel control section 30, and an evaluation monitor 35.

The liquid crystal display panel 20 is placed on the main body 18. The main body 18 is for pressing the liquid crystal display panel 20 placed on the main body 18. The main body 18 includes a placing table 1 on which the liquid crystal display panel 20 is placed, a pressing jig 11 for pressing the liquid crystal display panel 20 placed on the placing table 1, and a movable section 17 for causing the pressing jig 11 to move up and down.

The placing table 1 includes a table 2, a backlight 3, and a polarizing plate 4. The table 2 has a placing region 2a in which the liquid crystal display panel 20 to be evaluated (inspected) is placed. On a bottom surface of the placing region 2a, the backlight 3 and the polarizing plate 4 are stacked in this order. The liquid crystal display panel 20 to be evaluated (inspected) is stacked on the polarizing plate 4 so as to be placed within the placing region 2a.

The pressing jig 11 includes a pressing section 12 for pressing the liquid crystal display panel 20 and a reinforcing plate 13 for reinforcing the pressing section 12 and for connecting the pressing section 12 to the movable section 17. The pressing section 12 includes a transparent plate 15, an abutting section (gel member) 16 which makes contact with the liquid crystal display panel 20, and a polarizing plate 14.

The transparent plate 15 is made of a material having transparency, and is disposed so as to face a display region of the liquid crystal display panel 20 placed on the table 2. In the present embodiment, the transparent plate 15 is made of tempered glass having a thickness of approximately 2 mm to 5 mm. The transparent plate 15 can be made of any transparent and inflexible material, and can be made of, for example, quartz glass, sapphire glass, or the like.

The reinforcing plate 13 serves as a frame surrounding the transparent plate 15. In the present embodiment, the reinforcing plate 13 is an Alumite plate having a thickness of approximately 2 mm. In other words, the transparent plate 15 is provided in a region of the reinforcing plate 13 which region faces the liquid crystal display panel 20.

The abutting section 16 has a sheet-like shape and is disposed on a surface of the transparent plate 15 which surface faces the placing table 1. The abutting section 16 is made of a transparent gel material, and makes contact with the liquid crystal display panel 20 placed on the table 2 when the pressing jig 11 is moved down. In the present embodiment, the abutting section 16 is made of silicon rubber having a thickness of approximately 1 mm.

It is preferable that both of the transparent plate 15 and the abutting section 16 are made of a transparent material whose transparency to visible light is 80% or more.

Since the pressing section 12 includes the abutting section 16 which is a gel member, a uniform load can be more easily applied to the liquid crystal display panel 20, thereby allowing all the touch sensors within a pressed region to react. Further, a shock caused when the liquid crystal display panel 20 is pressed by the pressing section 12 can be absorbed by the abutting section 16. This makes it possible to prevent the liquid crystal display panel 20 from breaking or chipping when pressed by the pressing section 12.

The polarizing plate 14 is provided on a surface of the transparent plate 15 which surface is opposite to the surface on which the abutting section 16 is provided.

The movable section 17 connects the reinforcing plate 13 and the table 2. By moving the movable section 17, the pressing section 12 is moved up and down. In the present embodiment, the movable section 17 is constituted by a plurality of clamps 17a and 17d. The clamp 17a includes a main part 17a1 and a movable part 17a2, and the clamp 17b includes a main part 17b1 and a movable part 17b2. The main parts 17a1 and 17b1 are disposed around the placing region 2a of the table 2. The movable parts 17a2 and 17b2 are rotatably connected to the main parts 17a1 and 17b1, respectively. End parts of the movable parts 17a2 and 17b2 are connected to edge parts of the reinforcing plate 13.

As in the present embodiment, it is preferable that the movable section 17 is constituted by a plurality of parts (the clamps 17a and 17b in the present embodiment) so that the liquid crystal display panel 20 placed on the table 2 is uniformly pressed by the pressing jig 11. In the present embodiment, a pressure applied when the liquid crystal display panel 20 placed on the table 2 is pressed by the pressing jig 11 is set to 0.2 N/mm².

The liquid crystal display panel control section 30 is a circuit for (i) controlling driving (lighting) of liquid crystals of the liquid crystal display panel 20 placed in the placing region 2a of the table 2 and (ii) acquiring output signals from the touch sensors within the liquid crystal display panel 20 and supplying the output signals thus acquired to the evaluation monitor 35.

The liquid crystal display panel control section 30 includes a lighting control section (panel lightning means) 31 and a sensor data acquisition section (output acquisition section) 32.

The lighting control section 31 controls lighting of the liquid crystal display panel 20 by controlling driving of liquid crystals of the liquid crystal display panel 20 placed on the table 2. After the liquid crystal display panel 20 is placed on the table 2, the lighting control section 31 supplies, to the liquid crystal display panel 20, a drive signal for the liquid crystals which varies depending on evaluation. In response to the drive signal supplied from the lighting control section 31, the liquid crystal display panel 20 drives the liquid crystals. Thus, the liquid crystal display panel 20 is lit (an image is displayed).

The sensor data acquisition section 32 acquires sensor data of the touch sensors that is outputted from the liquid crystal display panel 20 when the liquid crystal display panel 20 is pressed by the pressing section 12, and then supplies the sensor data thus acquired to the evaluation monitor 35. Accordingly, by checking the sensor data displayed on the evaluation monitor 35, an operator can judge whether the touch sensors within the pressed liquid crystal display panel 20 are normally functioning or not.

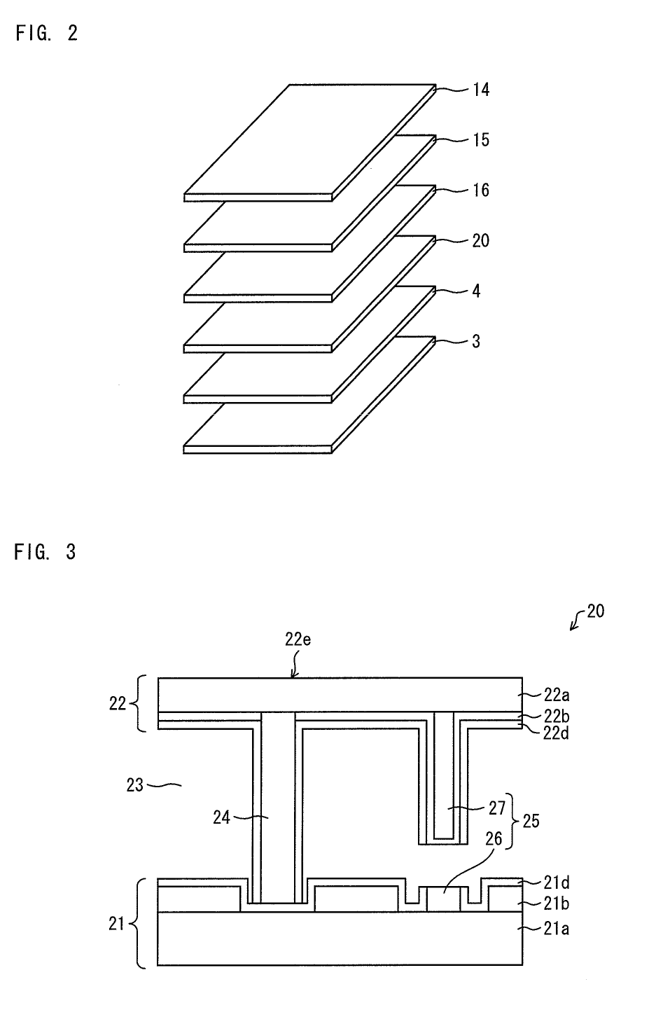

FIG. 2 is a perspective view illustrating the pressing section 12 and the members stacked within the placing region 2a.

In FIG. 2, the members are separated from each other. In fact, however, in a case where the liquid crystal display panel 20 is placed, the backlight 3, the polarizing plate 4, and the liquid crystal display panel 20 are in contact with each other, and the abutting section 16, the transparent plate 15, and the polarizing plate 14 are in contact with each other. Further, all the members are in contact with each other while the pressing section 12 is pressing the liquid crystal display panel 20.

As shown in FIG. 2, in a case where the liquid crystal display panel 20 is placed in the placing region 2a, the polarizing plate 4, the liquid crystal display panel 20, the abutting section 16, the transparent plate 15, and the polarizing plate 14 are disposed in this order from a side which light from the backlight 3 enters.

The abutting section 16 and the transparent plate 15 each have the substantially same area as the liquid crystal display panel 20 to be inspected. Accordingly, by pressing the liquid crystal display panel 20 by the pressing section 12 just one time, it is possible to check operation of all the touch sensors 25 disposed in the liquid crystal display panel 20.

(Configuration of Liquid Crystal Display Panel)

With reference to FIG. 3, the following describes how the liquid crystal display panel 20 is configured in a case where the liquid crystal display panel 20 is a non-defective product.

FIG. 3 is a cross-sectional view illustrating a configuration of a part of a pixel of the liquid crystal display panel 20 having a pressure detection type (switch-type) touch panel function.

As shown in FIG. 3, the liquid crystal display panel 20 includes an active matrix substrate 21, a counter substrate 22, a liquid crystal layer 23, and a columnar spacer 24. The active matrix substrate 21 and the counter substrate 22 sandwich the liquid crystal layer 23, and are disposed so as to face each other. The active matrix substrate 21 and the counter substrate 22 are supported by the columnar spacer 24.

In the following description, out of surfaces of the members constituting the liquid crystal display panel 20, a surface on an observer's side is referred to as “top surface”, and a surface on a backlight 3 side is referred to as “rear surface”.

The active matrix substrate 21 includes a lower substrate 21a, a TFT (not shown) for driving the pixel, a pixel electrode 21b, a touch electrode 26, and an alignment film 21d. The lower substrate 21a is made of glass or the like. The TFT (not shown) for driving the pixel, the pixel electrode 21b, and the touch electrode 26 are patterned on the lower substrate 21a. The alignment film 21d is disposed on a top surface (surface facing the liquid crystal layer 23) of the pixel electrode 21b.

The counter substrate 22 includes an upper substrate 22a, a color filter (not shown), a counter electrode 22b, a rib 27, and an alignment film 22d. The upper substrate 22a is made of glass or the like. The color filter, the counter electrode 22b, and the rib 27 are patterned on the upper substrate 22a. The alignment film 22d is disposed on a rear surface (surface facing the liquid crystal layer 23) of the counter electrode 22b. A top surface (surface opposite to a surface on which the counter electrode 22b etc. are provided) of the counter substrate 22 serves as a pressed surface 22e pressed by the pressing section 12.

The counter electrode 22b serves as a common electrode (COM electrode), and is disposed so as to face the pixel electrode 21b across the liquid crystal layer 23 and the alignment films 21d and 22d.

The rib 27 is a projection made of a dielectric material, and is disposed so as to face the touch electrode 26 across the liquid crystal layer 23. One end of the rib 27 is connected to the upper substrate 22a. A surface of the rib 27 is covered with the counter electrode 22b. The other end of the rib 27 protrudes in a direction from the upper substrate 22a to the active matrix substrate 21. The other end of the rib 27 is separated from the touch electrode 26. That is, the other end of the rib 27 faces the touch electrode 26 across the counter electrode 22b and the liquid crystal layer 23.

The touch electrode 26 is, for example, constituted by a TFT, and is produced in an identical production step in which the TFT element (not shown) for driving the pixel is produced.

The rib 27 and the touch electrode 26 serve as a touch sensor 25 for achieving the switch-type touch panel function of the liquid crystal display panel 20. The rib 27 is not limited in particular, provided that it protrudes in a direction from the upper substrate 22a to the active matrix substrate 21. In the present embodiment, the rib 27 has a column shape and has a cross-section having a rectangular shape.

The columnar spacer 24 is for defining a distance between the active matrix substrate 21 and the counter substrate 22. One end of the columnar spacer 24 is connected to the lower substrate 21a, and the other end of the columnar spacer 24 is connected to the upper substrate 22a.

When the liquid crystal display panel 20 is pressed, from a pressed surface 22e side, by the pressing section 12 (see FIG. 1), the rib 27 and the touch electrode 26 become electrically conductive with each other. Thus, the liquid crystal display panel 20 can detect the pressing. Note that the alignment film 22d is not provided on a surface of the rib 27 which surface faces the touch electrode 26 and the alignment film 21d is not provided on a surface of the touch electrode 26 which surface faces the rib 27 in order that the rib 27 and the touch electrode 26 become electrically conductive with each other when they make contact with each other.

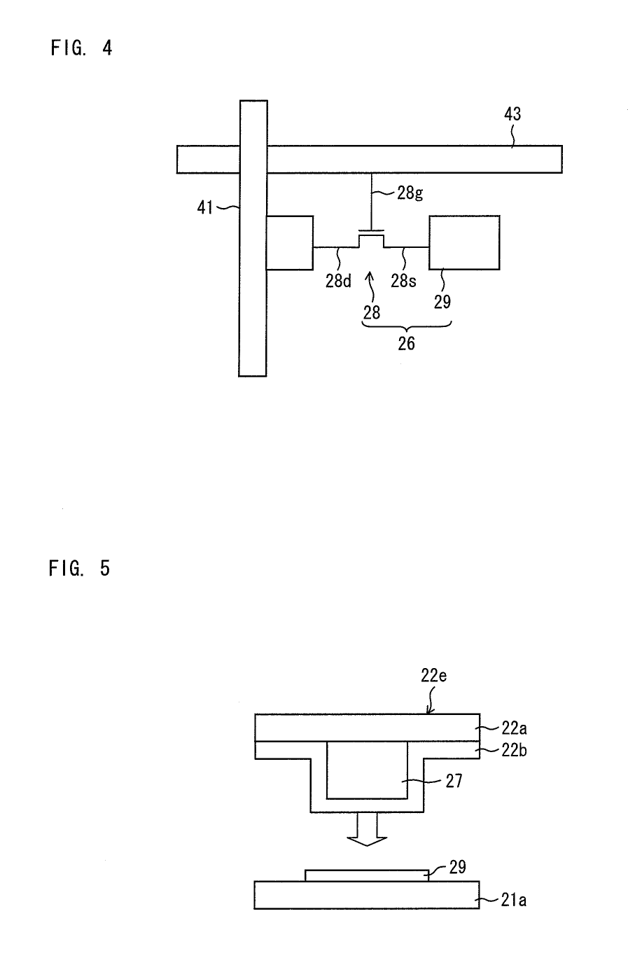

FIG. 4 is a plan view illustrating a configuration of the touch electrode 26 of the touch sensor 25. FIG. 5 is a cross-sectional view illustrating a configuration of a contact part of the touch sensor 25.

As partly shown in FIG. 4, the active matrix substrate 21 includes a plurality of source lines 41 and a plurality of scan lines 43 that intersect with the plurality of source lines 41. The source lines 41 are lines through which, when the rib 27 and the touch electrode 26 become electrically conductive with each other, electricity thus conducted flows. That is, the source lines 41 also serve as detection lines for detecting conduction between the rib 27 and the touch electrode 26.

The touch electrode 26 includes a switch TFT 28 and a contact surface 29. Via the contact surface 29, the touch electrode directly or indirectly makes contact with the rib 27. The contact surface 29 is disposed on a source 28s side of the switch TFT 28. As shown in FIG. 5, when the pressed surface 22e is pressed by the pressing section 12, the rib 27 and the contact surface 29 become conductive with each other.

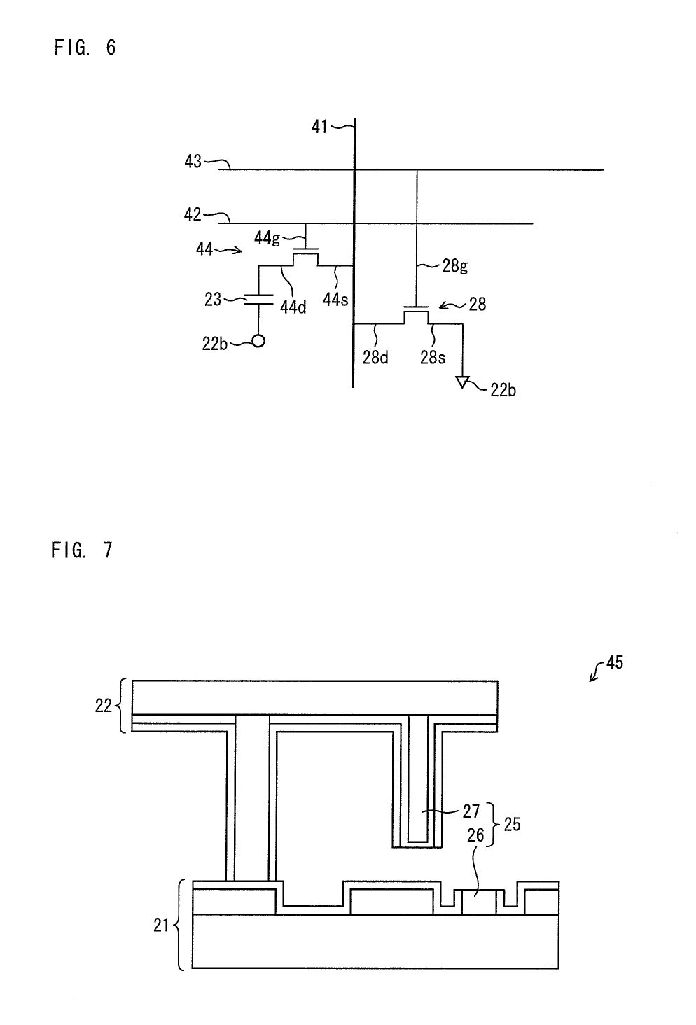

FIG. 6 is a diagram illustrating an equivalent circuit of a pixel of the liquid crystal display panel 20 in a case where the rib 27 is conductive with the switch TFT 28.

As shown in FIG. 6, a plurality of gate lines 42 are provided so as to intersect with the source lines 41 disposed in the active matrix substrate 21. The gate lines 42 are parallel with the scan lines 43. In the present embodiment, a pixel driving TFT 44 is disposed across a source line 41 from the switch TFT 28.

A gate 44g of the pixel driving TFT 44 is connected to the gate line 42. A source 44s of the pixel driving TFT 44 is connected to the source lines 41. The liquid crystal layer 23 which constitutes a capacitor is provided between a drain 44d of the pixel driving TFT 44 and the counter electrode 22b which is a COM electrode provided in the counter substrate 22. The pixel driving TFT 44 controls a display signal supplied from the source line 41.

A gate 28g of the switch TFT 28 is connected to the scan line 43. The source 28s of the switch TFT 28 is electrically connected, via the rib 27, to the counter electrode 22b which is a COM electrode provided in the counter substrate 22. A drain 28d of the switch TFT 28 is connected to the source line 41 which also serves as a detection line.

A reference voltage is supplied to the touch electrode 26 from the counter electrode 22b which is in contact with the rib 27, and the reference voltage is supplied, as a detection signal, to the source line 41. The detection signal is thus controlled by the switch TFT 28. Thus, the touch sensor function can be achieved.

(Defect)

In the liquid crystal display panel 20 having the switch-type in-cell touch panel function, it is assumed that there occur defects such as (i) line defects, (ii) point defects, (iii) the other defective mode defects, each of which does not occur in a normal liquid crystal display panel that does not have a switch-type in-cell touch panel function.

The arrangement of the evaluation apparatus 10 makes it possible to detect the (i) line defects and the (ii) point defects, which are defects specific to the liquid crystal display panel 20 having the switch-type in-cell touch panel function, out of these defects. The defects occur for the following reasons for example.

FIG. 7 is a diagram illustrating a configuration of a liquid crystal display device in which a defect occurs due to misalignment between the rib 27 and the touch electrode 26.

(1) Line defect: The rib 27 and the switch TFT 28 are electrically connected to each other by pressing the pressed surface 22e. However, in a case where leakage occurs in the switch TFT 28, this causes a reference voltage supplied from the source 28s of the switch TFT 28 to interfere with the source line 41. A line defect is caused by such unnecessary interference with the source line 41 by the switch TFT 28 in which leakage occurs.

(2) Point Defect: The liquid crystal display panel 45 shown in FIG. 7 is in a state in which the rib 27 and the touch electrode 26 are not disposed so as to face each other. That is, misalignment in pattern is generated at a production stage. When, in such a state where the misalignment in pattern is occurring, the rib 27 is moved down so as to make contact with wire and electrode that contribute lighting/displaying, a point defect is observed due to upper and lower leakage.

Specifically, the liquid crystal display panel 45 is pressed by the pressing section 12 in a state in which the liquid crystal display panel 45 is being lit (image is being displayed). When the rib 27 which is misaligned in pattern with the touch electrode 26 is moved down and makes contact with a wire (e.g., pixel electrode, pixel driving TFT, and the like) disposed in the active matrix substrate 21 which wire contributes to lighting, an electric current flowing through the wire flows into the rib 27. This causes leakage between the active matrix substrate 21 and the counter substrate 22. A point defect is observed due to the leakage thus occurred.

According to the arrangement of the evaluation apparatus 10, the pressing section 12 has transparency. Accordingly, in a state where the liquid crystal display panel 20/45 to be inspected is being lit by the lighting control section 31 and being pressed by the pressing section 12, an operator can observe, through the pressing section 12, a lighting state of a region of the liquid crystal display panel 20/45 which region is being pressed. Consequently, according to the arrangement of the evaluation apparatus 10, it is possible to check whether or not the liquid crystal display panel 20/45 has a line defect and a point defect.

(3) Other Defective Mode: In a case where an insulator (e.g., alignment film or foreign matter) is present between the rib 27 and the touch electrode 26, an error is invited in operation of the switch TFT 28. However, this causes no influence on lighting/displaying of the liquid crystal display panel 20. Accordingly, this kind of defect does not require the pressing section 12 to have transparency, and therefore the pressing section 12 may be a metal plate such as a stainless plate.

The liquid crystal display panel 20 having a switch-type in-cell touch panel function has hardly ever been commercialized. Moreover, conventionally, an image display region for displaying an image and a touch panel region were separate from each other. It was therefore unlikely that a display defect occurs in an image display region by pressing a touch panel part. Accordingly, there has been little necessity for checking presence or absence of a defect which is caused by pressing a liquid crystal display panel having a switch-type in-cell touch panel function in a state in which the liquid crystal display panel is being lit (image is being displayed).

According to the evaluation apparatus 10, the lighting control section 31 lights the liquid crystal display panel 20 including switch-type touch sensors. Then, the pressing section 12 presses the liquid crystal display panel 20 that is being lit by the lighting control section 31. Then, the sensor data acquisition section 32 acquires outputs from the touch sensors 25 within a pressed region of the liquid crystal display panel 20. The sensor data acquisition section 32 causes the evaluation monitor 35 to display an image showing operation states of the touch sensors 25 on the basis of the sensor data thus acquired. It is thus possible to check operation of the touch sensors 25 within the pressed region.

Further, since the pressing section 12 is made of a material having transparency, an operator can check, in a state in which the liquid crystal display panel 20 is being lit and being pressed, a lighting state of a region of the liquid crystal display panel 20 which region is being pressed. This makes it possible to check presence or absence of a lighting defect, such as the (i) line defect and the (ii) point defect, which occurs due to a defect of the touch sensors 25 and which can be found by lighting and pressing the liquid crystal display panel 20.

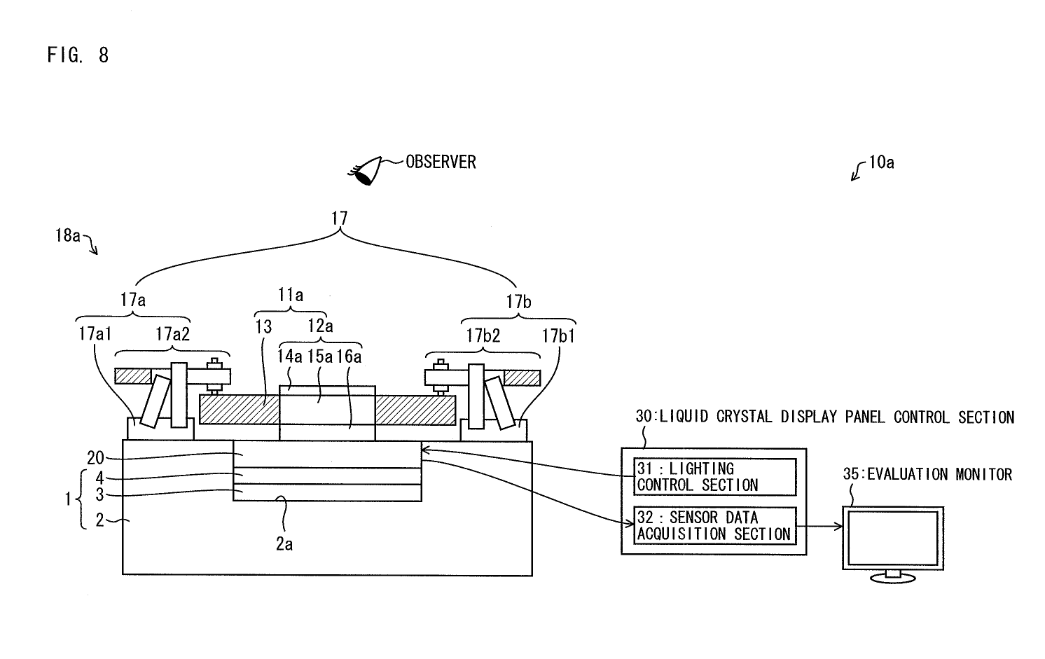

An area of the pressing section 12 may be smaller in size than that of the liquid crystal display panel 20 to be inspected, as shown in FIG. 8.

Modification 1

FIG. 8 is a diagram illustrating a first modification of the evaluation apparatus.

As shown in FIG. 8, an evaluation apparatus (defect inspecting apparatus) 10a includes a main body 18a, a liquid crystal display panel control section 30, and an evaluation monitor 35. The main body 18a includes a placing table 1, pressing jig 11a for pressing a liquid crystal display panel 20 placed on the placing table 1, and a movable section 17 for causing the pressing jig 11a to move up and down.

The pressing jig 11a includes a pressing section 12a that is smaller in area than the pressing section 12, and a reinforcing plate 13 for reinforcing the pressing section 12a and for connecting the pressing section 12a to the movable section 17.

The pressing section 12a includes an abutting section 16a, a transparent plate 15a, and a polarizing plate 14a that are stacked in this order from a side which light emitted from a backlight 3 enters.

An area of the pressing section 12a is smaller in size than an area of the liquid crystal display panel 20. According to the evaluation apparatus 10a, the liquid crystal display panel 20 is pressed plural times, and an operator thus inspects a lighting state of the liquid crystal display panel 20 and operation states of touch sensors 25 within a region that is being pressed.

For example, in a case where the area of the pressing section 12a is half as large as the area of the liquid crystal display panel 20, the liquid crystal display panel 20 is pressed twice. Thus, an entire region of the liquid crystal display panel 20 is inspected.

In a case where an area of the liquid crystal display panel 20 that is pressed one time is reduced, a load is more easily uniformly applied to the liquid crystal display panel 20. This surely allows all the touch sensors 25 within a region pressed by the pressing section 12a to react. It is therefore possible to more surely evaluate operation states of the touch sensors 25 within the pressed region of the liquid crystal display panel 20.

Inspection of pressing a liquid crystal display panel as disclosed in Patent Literature 1 is for checking deformation and recovery of a spacer within a cell (within a liquid crystal display panel) or strength of the liquid crystal display panel. Accordingly, in the evaluation apparatus disclosed in Patent Literature 1, a load of approximately 10 kgf to 50 kgf is applied to the liquid crystal display panel with the use of a jig of approximately 1 mm square or φ10 mm. In this case, a pressure applied to the liquid crystal display panel is approximately 1 N/mm² to 5 N/mm².

Meanwhile, the evaluation apparatus 10a of the present embodiment presses the liquid crystal display panel 20 in order to inspect operation states of the touch sensors 25 provided in the liquid crystal display panel 20.

For example, in a case where the liquid crystal display panel 20 has a size of 2 inches and where the liquid crystal display panel 20 is divided into two parts which are pressed separately, the pressing section 12a has a size of approximately 20 mm×30 mm, which is 6 times larger than the area of the jig of the evaluation apparatus of Patent Literature 1, and a pressure applied to the liquid crystal display panel 20 is approximately 0.2 N/mm². Accordingly, the evaluation apparatus 10a can conduct inspection while causing less damage on the liquid crystal display panel 20 as compared with the case where deformation and recovery of a spacer within a cell (within the liquid crystal display panel) or strength of the liquid crystal display panel are inspected.

Modification 2

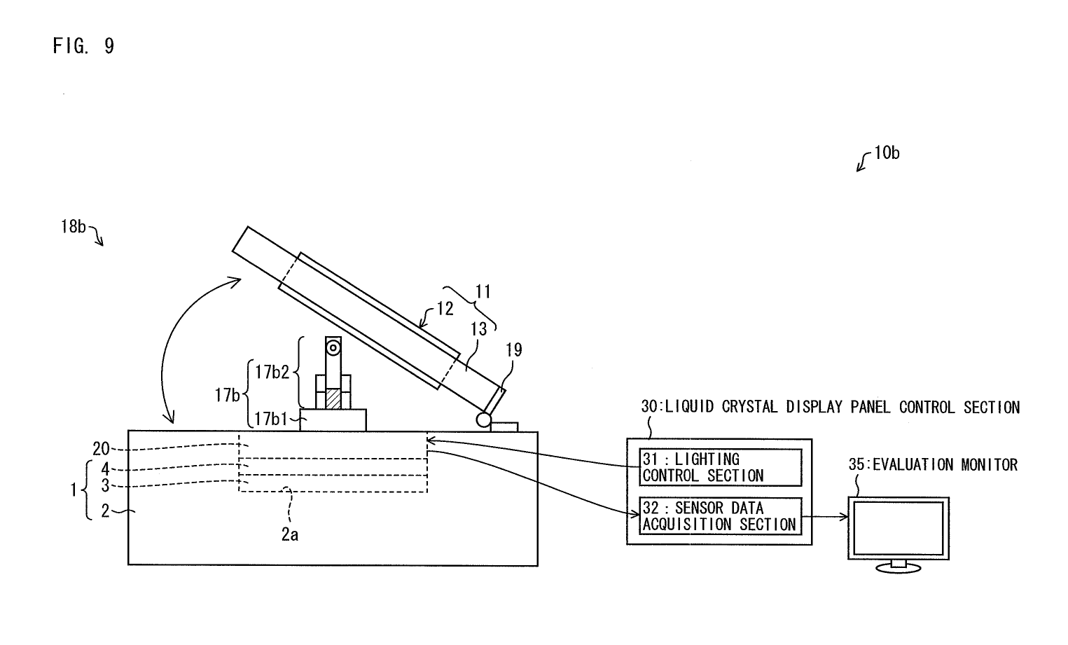

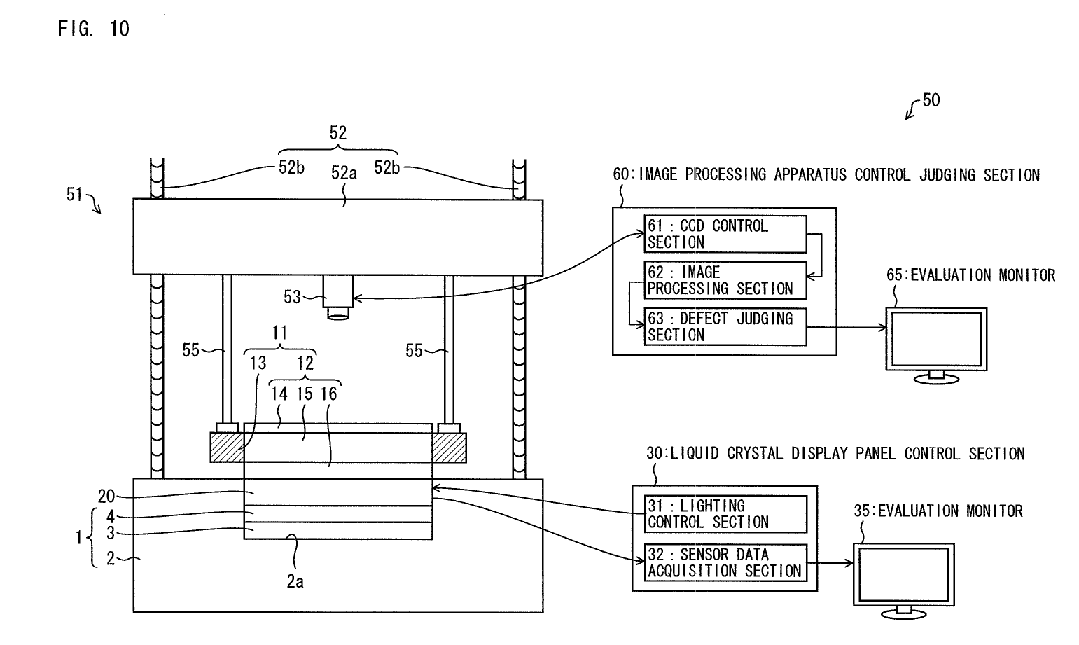

The main body 18 described above is configured such that the reinforcing plate 13 of the pressing jig 11 is connected to the ends of the movable parts 17a2 and 17b2 of the clamps 17a and 17b. However, the present embodiment is not limited to this. It is only necessary that the pressing jig 11 be provided on the table 2 so as to be able to press the liquid crystal display panel 20 placed in the placing region 2a of the table 2, for example, as shown in FIG. 9.

FIG. 9 illustrates a second modification of the main body.

An evaluation apparatus 10b shown in FIG. 9 includes a main body 18b in replacement of the main body 18 of the evaluation apparatus 10. The other configuration of the evaluation apparatus 10b is similar to that of the evaluation apparatus 10. The main body 18b has an arrangement such that a hinge 19 is added to the main body 18.

FIG. 9 shows the main body 18b viewed from a side on which a clamp 17b is provided.

As shown in FIG. 9, the main body 18b includes the hinge 19 disposed on one end of a reinforcing plate 13. The hinge 19 connects a pressing jig 11 and a table 2.

The reinforcing plate 13 of the main body 18b is not connected to ends of a movable part 17b2 of the clamp 17b and of a movable part 17a2 (not shown in FIG. 9) of a clamp 17a.

Since the hinge 19 is provided on one end of the reinforcing plate 13, and the pressing jig 11 and the table 2 are connected to each other by the hinge 19, the pressing jig 11 can be opened and closed on the hinge 19 as shown by the arrow in FIG. 9. In a case where the pressing jig 11 can be thus opened and closed, it becomes easy to attach or detach the liquid crystal display panel 20 to/from the placing region 2a of the table 2. This allows an improvement in operation efficiency.

### Embodiment 2

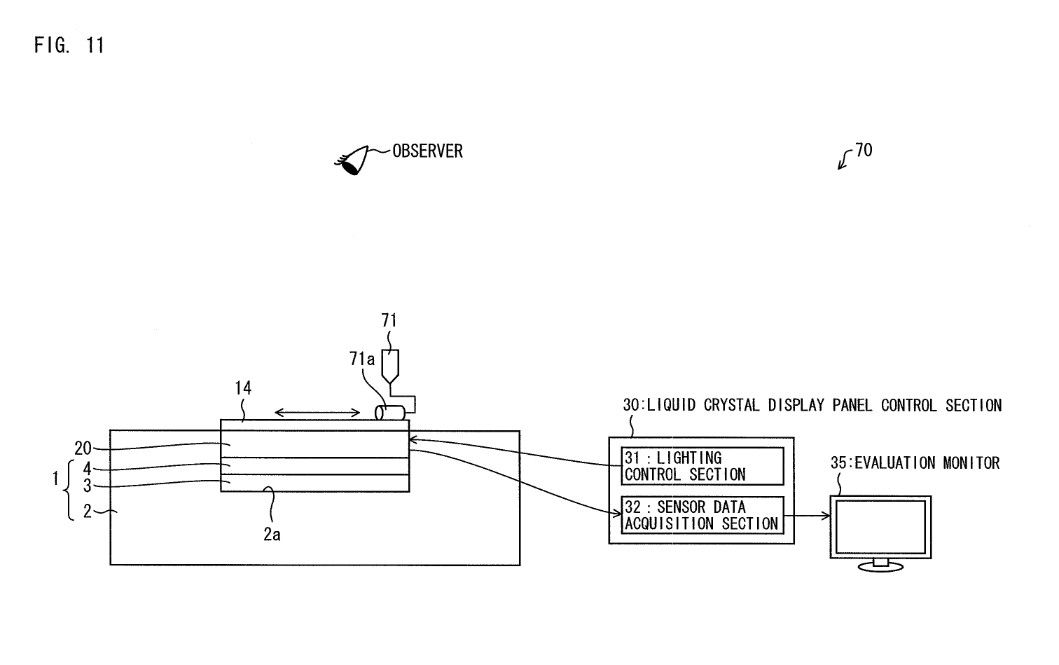

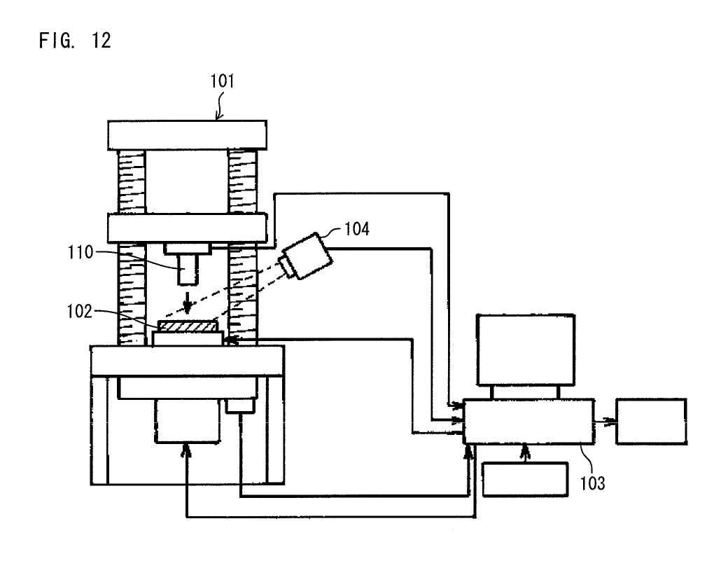

Embodiment 2 of an evaluation apparatus of the present invention is described below with reference to FIG. 10.

For convenience of description, members that have identical functions to those in the drawings described in Embodiment 1 are given identical reference numerals, and are not explained repeatedly.

FIG. 10 is a schematic view illustrating a configuration of an evaluation apparatus 50 of Embodiment 2.

In the evaluation apparatus 10, an operator observes a lighting defect of the liquid crystal display panel 20 with the naked eye. Meanwhile, the evaluation apparatus 50 of the present embodiment includes a CCD (imaging means) 53 for imaging a region of the liquid crystal display panel 20 which region is being pressed by the pressing section 12.

In the evaluation apparatus 50, an image is taken by the CCD (imaging means) 53, and it is determined, based on the image, whether or not a lighting defect is present in the liquid crystal display panel 20.

The evaluation apparatus 50 includes a main body 51, a liquid crystal display panel control section 30, an evaluation monitor 35, an image processing apparatus control judging section 60, and an evaluation monitor 65. The main body 51 includes a placing table 1, a pressing jig 11, a CCD 53, a movable section 52 for causing the pressing jig 11 to move up and down, and support sections 55 for supporting the pressing jig 11.

The movable section 52 includes an elevated table 52a which moves up and down and a plurality of screws 52b which support the elevated table 52a and which allow the elevated table 52a to move up and down. The elevated table 52a is provided with a plurality of holes. The plurality of screws 52b provided on the table 2 of the placing table 1 are engaged with the respective holes of the elevated table 52a. The elevated table 52a moves up and down along the plurality of screws 52b. This causes the pressing jig 11 to move up and down.

The support sections 55 support the pressing jig 11 horizontally, and are provided between the elevated table 52a and the pressing jig 11. One ends of the plurality of support sections 55 are provided on a surface of the elevated table 52a which surface faces the placing table 1, and the other ends of the support sections 55 are provided on a surface of the reinforcing plate 13 which surface faces the elevated table 52a. In the present embodiment, the support sections 55 are stainless round bars of φ10 mm.

The CCD 53 takes an image of how, in a state in which the liquid crystal display panel 20 is being pressed by the pressing section 12, the liquid crystal display panel 20 placed on the placing table 1 is lit in a region that is being pressed.

The CCD 53 is provided so as to face, across the pressing section 12, the liquid crystal display panel 20 to be imaged by the CCD 53. That is, the CCD 53 is provided on a surface of the elevated table 52a which surface faces the pressing jig 11 so as to be located in a region facing the transparent plate 15.

The image processing apparatus control judging section 60 includes a CCD control section 61, an image processing section 62, and a defect judging section (defect judging means) 63.

The CCD control section 61 controls driving of the CCD and acquires an image taken by the CCD 53. After acquiring the image from the CCD 53, the CCD control section 61 supplies the image thus acquired to the image processing section 62.

The image processing section 62 carries out image processing of converting the image acquired from the CCD control section 61 into a judging image for judging whether or not a defect is present. The image processing section 62 supplies the image thus subjected to the image processing to the defect judging section 63.

The defect judging section 63 acquires, from the image processing section 62, the image subjected to the image processing, and then judges whether the image acquired from the image processing section 62 is good or not, for example by examining whether a pattern of the image acquired from the image processing section 62 matches that of an image registered in advance. Then, the defect judging section 63 causes the evaluation monitor 65 to display a result of the judgment. The defect judging section 63 makes it possible to judge whether or not there is a defect, without depending on judgment of an operator who is carrying out inspection. This allows for an improvement in defect inspection accuracy.

Alternatively, the image processing section 62 may convert the image acquired from the CCD control section 61 into a judging image indicative of a two-dimensional luminance distribution, and then supply the image thus obtained to the defect judging section 63, and the defect judging section 63 may judge whether or not there is a defect, by judging whether or not the image indicative of a two-dimensional luminance distribution has a portion whose luminance exceeds an upper limit or falls below a lower limit of luminance.

As described above, according to the arrangement of the evaluation apparatus 50, an operator who is carrying out inspection can check a lighting state of the liquid crystal display panel 20 on the basis of an image taken by the CCD 53. That is, the operator need not directly observe a region of the liquid crystal display panel 20 which region is being pressed. This allows an improvement in inspection operation efficiency.

Further, since the CCD 53 is disposed in a region facing, across the pressing section 12, the liquid crystal display panel 20 to be imaged by the CCD 53, a region of the liquid crystal display panel 20 which is being pressed by the pressing section 12 can be imaged from a direction vertical to the liquid crystal display panel 20.

This makes it possible to take a clearer image as compared with a case where the region of the liquid crystal display panel 20 which is being pressed by the pressing section 12 is imaged from a direction diagonal to the liquid crystal display panel 20. This allows for an improvement in defect inspection accuracy.

### Embodiment 3

Embodiment 3 of an evaluation apparatus of the present invention is described below with reference to FIG. 11.

For convenience of description, members that have identical functions to those in the drawings described in Embodiments 1 and 2 are given identical reference numerals, and are not explained repeatedly.

FIG. 11 is a schematic view illustrating a configuration of an evaluation apparatus 70 of Embodiment 3.

The evaluation apparatus 70 includes a placing table 1, a polarizing plate 14, a roller 71, a liquid crystal display panel control section 30, and an evaluation monitor 35. The roller 71 has a rotating section (pressing section) 71a which is made of a transparent material. The liquid crystal display panel 20 provided in a placing region 2a of the placing table 1 can be pressed by the rotating section 71a.

A material of which the transparent rotating section 71a of the roller 71 is, for example, acrylic, polycarbonate, or the like, and can be a transparent resin whose transmittance to visible light is 80% or more. An axis about which the rotating section 71a of the roller 71 is rotated can be made of, for example, a metallic material such as stainless.

After the liquid crystal display panel 20 is placed in the placing region 2a of the placing table 1, the polarizing plate 14 is disposed on a surface of the liquid crystal display panel 20. Then, the liquid crystal display panel 20 is pressed by the roller 71 via the polarizing plate 14. In a state in which the liquid crystal display panel 20 is being pressed, the roller 71 is moved back and forth in a direction parallel to a surface of the liquid crystal display panel 20.

Thus, a sensor data acquisition section 32 acquires outputs from touch sensors 25 disposed within a region pressed by the roller 71 in the liquid crystal display panel 20. Then, the sensor data acquisition section 32 causes the evaluation monitor 35 to display the outputs from the touch sensors 25. Consequently, in a state in which the liquid crystal display panel 20 is being lit, an operator can check operation of the touch sensors 25 disposed within the region pressed by the roller 71 and a lighting state of the liquid crystal display panel 20.

The roller 71 is moved parallel to the liquid crystal display panel 20 in a state in which the liquid crystal display panel 20 is being pressed. It is therefore possible to check a lighting state of the liquid crystal display panel 20 achieved immediately after it is pressed. That is, it is possible to check how a lighting state in a region pressed by the roller 71 changes with time immediately after the region is pressed.

The evaluation apparatus 70 may further include a transparent silicon rubber sheet (not shown) between the liquid crystal display panel 20 and the polarizing plate 14. This allows the liquid crystal display panel 20 to be uniformly pressed by the roller 71.

The present invention is not limited to the description of the embodiments above, but may be altered by a skilled person within the scope of the claims. An embodiment based on a proper combination of technical means disclosed in different embodiments is encompassed in the technical scope of the present invention.

As described above, a defect inspecting apparatus of the present invention for inspecting touch sensors of a liquid crystal display panel for defects, the touch sensors being switch-type touch sensors, includes: panel lightning means for lighting the liquid crystal display panel to be inspected; a pressing section for pressing the liquid crystal display panel that is being lit; and an output acquisition section for acquiring outputs from touch sensors disposed within a region of the liquid crystal display panel which region is pressed by the pressing section, the pressing section being made of a material having transparency.

In order to attain the above object, a defect inspecting method of the present invention for inspecting touch sensors of a liquid crystal display panel for defects, the touch sensors being switch-type touch sensors, includes the steps of: lighting the liquid crystal display panel to be inspected; causing a pressing section made of a material having transparency to press the liquid crystal display panel that is being lit; and acquiring outputs from touch sensors disposed within a region of the liquid crystal display panel which region is pressed by the pressing section.

The liquid crystal display panel including the switch-type touch sensors has not only a function of displaying an image when it is lit, but also a function of detecting pressing when it is pressed, i.e., function as a touch panel.

According to the arrangement, the panel lightning means lights the liquid crystal display panel including the switch-type touch sensors, i.e., causes the liquid crystal display panel to display an image. The pressing section presses the liquid crystal display panel lit by the lighting means. Then, the output acquisition section acquires outputs from touch sensors within a region of the liquid crystal display panel which region is being pressed. It is therefore possible to check operation of the touch sensors within the pressed region.

The pressing section is made of a material having transparency. Accordingly, in a state in which the liquid crystal display panel is being lit and being pressed, it is possible to check a lighting state within the region of the liquid crystal display panel which region is being pressed. This makes it possible to check presence or absence of a lighting defect which occurs when the liquid crystal display panel is lit and pressed. According to the arrangement, it is thus possible to inspect switch-type touch sensors of a liquid crystal display panel for defects by checking a display state of a region to which a load is being applied.

It is preferable that the defect inspecting apparatus of the present invention further includes imaging means for imaging the region of the liquid crystal display panel which region is being pressed by the pressing section.

According to the arrangement, in a state in which the liquid crystal display panel is being lit and being pressed, a region that is being pressed can be imaged by the imaging means. An operator can thus check, based on an image taken by the imaging means, a lighting state of the liquid crystal display panel. That is, the operator need not directly observe the region that is being pressed. This allows for an improvement in operation efficiency of inspection.

It is preferable that the imaging means is disposed so as to face, across the pressing section, the region of the liquid crystal display panel which region is pressed by the pressing section.

Further, it is preferable that the imaging means is disposed so as to face, across the pressing section, the liquid crystal display panel to be imaged by the imaging means.

According to the arrangement, the imaging means can image, from a direction vertical to the liquid crystal display panel, the region of the liquid crystal display panel which region is being pressed by the pressing section. This makes it possible to take a clearer image as compared with a case where the region of the liquid crystal display panel which is being pressed by the pressing section is imaged at an oblique angle to the liquid crystal display panel. This allows for an improvement in defect inspection accuracy.

It is preferable that the defect inspecting apparatus of the present invention further includes defect judging means for judging, on a basis of an image of the liquid crystal display panel which image is taken by the imaging means, whether or not there is a defect.

According to the arrangement, it is possible to judge whether or not there is a defect, without depending on judgment of an operator who is carrying out inspection. This allows for an improvement in defect inspection accuracy.

It is preferable that an area of the pressing section is smaller in size than an area of the liquid crystal display panel to be inspected.

According to the arrangement, a force can be more uniformly applied from the pressing section to the liquid crystal display panel within the region of the liquid crystal display panel which region is being pressed by the pressing section. This allows the touch sensors within the region pressed by the pressing section to react more easily. Consequently, defect inspection accuracy can be improved.

It is preferable that the pressing section includes a gel member which makes contact with the liquid crystal display panel to be inspected. According to the arrangement, the liquid crystal display panel is pressed by an abutting section which is the gel member. This allows a uniform load to be more easily applied to the liquid crystal display panel, thereby allowing all the touch sensors within the pressed region to react. Further, the gel member can absorb shock that occurs when the pressing section presses the liquid crystal display panel. This makes it possible to prevent the liquid crystal display panel from being broken or chipping when pressed by the pressing section.

It is preferable that the pressing section is moved parallel to the liquid crystal display panel while pressing the liquid crystal display panel.

According to the arrangement, the pressing section is moved parallel to the liquid crystal display panel while pressing the liquid crystal display panel. This makes it possible to check not only a lighting state of the liquid crystal display panel achieved while the liquid crystal display panel is being pressed, but also a lighting state of the liquid crystal display panel achieved immediately after the liquid crystal display panel is pressed.

The present invention makes it possible to observe a lighting state of a pressed region by lighting and pressing a liquid crystal display panel. Accordingly, the present invention can be applied not only to inspection of a liquid crystal display panel including a switch-type touch sensor, but also to inspection of a liquid crystal display panel.

1: Placing table

2: Table

1. A defect inspecting apparatus for inspecting touch sensors of a liquid crystal display panel for defects, the touch sensors being switch-type touch sensors, comprising:
panel lightning section for lighting the liquid crystal display panel to be inspected;
a pressing section for pressing the liquid crystal display panel that is being lit; and
an output acquisition section for acquiring outputs from touch sensors disposed within a region of the liquid crystal display panel which region is pressed by the pressing section,
the pressing section being made of a material having transparency.

2. The defect inspecting apparatus according to claim 1, further comprising an imaging unit for imaging the region of the liquid crystal display panel being pressed by the pressing section.

3. The defect inspecting apparatus according to claim 2, wherein the imaging unit is disposed so as to face, across the pressing section, the liquid crystal display panel to be imaged by the imaging unit.

4. The defect inspecting apparatus according to claim 2, further comprising a defect judging unit for judging, on a basis of an image of the liquid crystal display panel which image is taken by the imaging unit, whether or not there is a defect.

5. The defect inspecting apparatus according to claim 1, wherein an area of the pressing section is smaller in size than an area of the liquid crystal display panel to be inspected.

6. The defect inspecting apparatus according to claim 1, wherein the pressing section includes a gel member which makes contact with the liquid crystal display panel to be inspected.

7. The defect inspecting apparatus according to claim 1, wherein the pressing section is configured to move parallel to the liquid crystal display panel while pressing the liquid crystal display panel.

8. A defect inspecting method for inspecting touch sensors of a liquid crystal display panel for defects, the touch sensors being switch-type touch sensors, comprising:
lighting the liquid crystal display panel to be inspected;
causing a pressing section made of a material having transparency to press the liquid crystal display panel that is being lit; and
acquiring outputs from touch sensors disposed within a region of the liquid crystal display panel which region is pressed by the pressing section.
